(19) United States
(12) Patent Application Publication
(10) Pub. No.: US 2007/0295275 A1
(43) Pub. Date: Dec. 27, 2007

(54) Epitaxial Reactor Cooling Method and Reactor Cooled Thereby

(76) Inventors: Vincenzo Ogliari, Capergnanica (IT); Giuseppe Tarenzi, Castiglione d'Adda (IT); Marco Puglisi, Catania (IT); Natale Speciale, Mazara del Vallo (IT); Franco Preti, Milano (IT)

Correspondence Address: KATTEN MUCHIN ROSENMAN LLP, 575 MADISON AVENUE, NEW YORK, NY, 10022-2585, US

(21) Appl. No.: 11/661,581

(22) PCT Filed: Oct. 1, 2004
(86) PCT No.: PCT/IT04/00542

§ 371 Date: May 7, 2007

(51) Int. Cl. C23C 16/52

(52) U.S. Cl. 118/719; 118/79; 427/248.1

(57) ABSTRACT

The invention relates to a method for cooling the walls of the reaction chamber (2) of a reactor for chemical vapour deposition.

The method consists in selectively cooling with water at least one predetermined zone of the wall of the chamber (2), to remove a different heat flow compared with the adjacent zones so as to obtain substantially uniform temperature distribution of the reaction chamber (2).

In a preferred embodiment, the selectively-cooled zone is the zone above the susceptor (5) and is delimited by two ribs (8, 9).

The invention also includes a reactor and a reaction chamber (2) for carrying out the cooling method.

The invention relates to a method for cooling the chamber of an epitaxial reactor used in the production of substrates by chemical vapour deposition (the CVD process).

As is known, these reactors are above all used in the microelectronics industry for the production of semiconductor components; to this end they comprise a reaction chamber in which the epitaxial growth of the substrates (also commonly known as wafers) takes place, with the substrates being supported by a susceptor.

There are two types of reactor, defined in relation to the path of the reaction gases: horizontal reactors and vertical reactors.

The method of the present invention relates to both types of reactor, although in the description below reference will be made chiefly to the former, wherein the reaction chamber is substantially a quartz bell with a vaguely parallelepipedal shape, crossed horizontally by the flow of gases from one side to the other.

In horizontal reactors, the susceptor comprises a disc that rotates inside the reaction chamber and the substrates are located on its upper surface in respective seats of corresponding shape. The susceptor disc is usually made of graphite or another conductive material able to withstand high temperatures so that it can be heated using electromagnetic induction or radiance with lamps.

The CVD process is the result of a chemical reaction that takes place at high temperatures (above 1.000° C.), such that it is a known practice to cool the walls, generally quartz, of the reaction chamber.

The cooling may be with air or water: it should, however, not be excessive because if the wall temperature decreases below preset levels, there is a risk. This risk concerns mainly the zones of the chamber that are less hot and is accentuated in the case where the cooling fluid is water, since its heat exchange with the quartz bell is greater than that of air.

The technical problem underlying the present invention is therefore to cool an epitaxial reactor in such a way as to prevent excessive lowering of the temperature, that could cause the aforementioned negative consequences.

This problem is solved by a method characterised by cooling the reaction chamber selectively, namely it removes different heat fluxes from different zones of the chamber, thereby keeping its temperature distribution substantially uniform; this enables to better control the process and prevents the temperature in given points falling below acceptable limits as a result of any unforeseen occurrences.

According to a preferred embodiment, when the method according to the invention is carried out in horizontal reactors, the reaction chamber is cooled by water (or another appropriate liquid) sprayed in the zone above the susceptor disc. The invention also comprises an epitaxial reactor cooled in accordance with the method described above, and a reaction chamber purposely made.

Further features of the invention will emerge more clearly from the following description of a non-limiting example of the invention, shown in the accompanying drawings wherein:

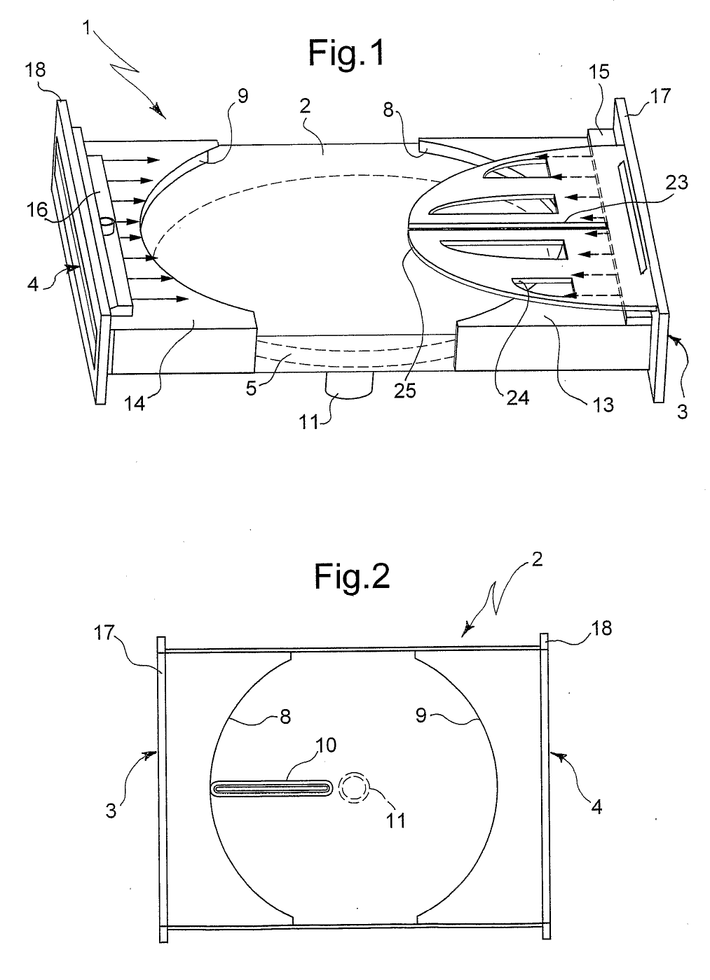

FIG. 1 is a diagrammatic perspective view of an epitaxial reactor cooled according to the present invention;

FIG. 2 is a plan view of the reaction chamber of the reactor in FIG. 1;

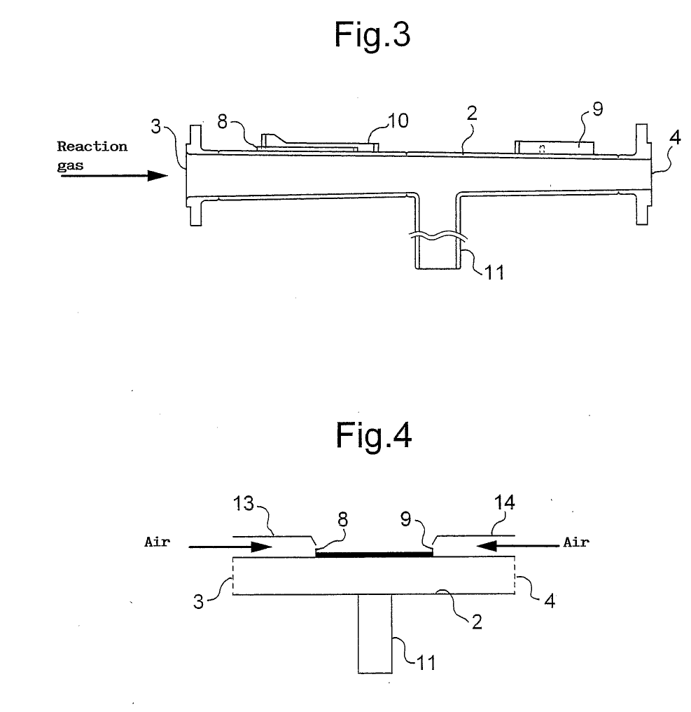

FIG. 3 is a side view of the reaction chamber in FIG. 2;

FIG. 4 is a diagrammatic representation of the cooling fluxes in the preceding reaction chamber.

In these drawings, the reference 1 generally indicates an epitaxial reactor for the chemical vapour deposition (CVD) of substances, like those typically used for the production of semiconductors in the microelectronics industry.

The reactor 1 is of the horizontal flow type and comprises a reaction chamber 2 with a substantially parallelepipedal shape, that has an inlet opening 3 and an outlet opening 4 on two opposite faces for the flow of gases in the reaction chamber, the velocity of which is indicated by the arrow in FIG. 3.

The reaction chamber 2 is made of quartz and is slightly tapered towards the gas outlet side, while in the zone above the susceptor disc 5 (indicated only by the broken lines in FIG. 1), it is coated preferably by a thin layer of gold paint that reflects the heat radiated during the process.

The zone of the chamber 2 located above the susceptor 5 is delimited by two circular-arc-shaped ribs 8, 9 that extend from one side of the chamber to the other; moreover, the chamber is provided with a radial window 10 known per se for the use of optical means for monitoring the susceptor position.

The lower part of the chamber 2 has the usual hollow stem 11 through which the shaft for rotating the susceptor 5 extends. This shaft is not shown in the drawings. As can be seen in FIG. 1, in connection with the inlet and outlet openings 3 and 4 of the chamber, there are respective screens 13 and 14; the latter are coverings made of sheet metal or another appropriate material, which extend around the zones of the reaction chamber 2 that are outside the ribs 8 and 9.

The purpose of the screens is to prevent the cooling water supplied using the distributors 15 and 16 from falling into the zones of the chamber 2 that are furthest from the susceptor and therefore have a lower temperature. To this end, the screens 13, 14 are fixed to flanges 17, 18 associated with the inlet and outlet openings 3 and 4, and have their free edge shaped in the same manner as the ribs 8, 9. The distance between the screens and the quartz of the chamber 2 is preferably approximately 10 mm.

In a preferred embodiment of the invention there is, above the screen 13, a plate 23 that supports additional nozzles 24, 25 for also spraying water above the central zone of the reaction chamber 2.

The description provided hereinabove makes it possible to understand how the reactor 1 is cooled in accordance with the method of the invention.

The distributors 15, 16 feed the water over the respective screens 13, 14 as indicated by the arrows in FIG. 1. The water then flows in a cascade along the curved edge of aforesaid screens and falls onto the reaction chamber 2, in the zone of the latter that is above the susceptor between ribs 8 and 9.

The ribs in fact form barriers that prevent the water from flowing back towards the openings 3 and 4, so that it falls laterally along the free edge of the chamber 2 between the two ribs 8 and 9, to be collected subsequently in a tank located underneath and not shown in the drawings.

A third flow of water is sprayed by the nozzles 24, 25 with some velocity towards the central part of the chamber 2. This is the most critical zone, since it is subjected to the greatest heat flux from the susceptor and the moving water can exchange heat with the quartz better, thereby avoiding harmful boiling phenomena that could cause the detachment of the reflective paint applied in this zone.

The selective cooling thus provided makes it possible to maintain substantially uniform temperature distribution in the quartz of the reaction chamber 2, since coolest zones thereof (that is to say, those furthest away from the susceptor 5) are not sprinkled with water while its central zones are constantly sprayed to remove the heat radiated by the susceptor below.

In particular, it can be said that there is a high heat flux or power (i.e. the quantity of heat per unit of time) removal from the part sprinkled with water by forced convection, whereas the heat flux removed in the dry zones is less and the exchange takes place by natural air convection and radiation.

It should however be noted that in order to obtain either greater cooling or better process control, the dry zones can be licked by forced ventilation that circulates air between the upper wall of the chamber 2 and the screens 13, 14, as indicated diagrammatically in FIG. 4. In this case, these zones are therefore cooled by forced convection.

The uniform temperature distribution obtained using the method of the invention enables easier and more effective control of the conditions of the reaction chamber 2, in order to prevent excessive drops in temperature that could have the aforementioned damaging consequences (polymerisation of the gaseous substances and their subsequent condensation or deposition on the chamber walls).

It is clear that the teaching of selectively cooling the reaction chamber can also be carried out differently from the embodiment explained above, to suit the different epitaxial reactors (both horizontal and vertical) in use.

For example, the fact that only the upper zone of the reaction chamber 2 is water cooled as described above, does not prevent its lower part from also being cooled using the same principle.

In this case it will be necessary to provide means for spraying water from below towards the zone of the chamber that is underneath the susceptor 5 and around the hollow stem 11.

It should also be understood that a known cooling system can alternatively be installed under the reaction chamber, such as, for example the system described in European Patent No. 730679, in the name of the same present applicant.

In this connection, it should be emphasised that the selective cooling of the present invention makes it possible to apply the reflective gold coating, only in the zone where the susceptor radiation is greatest. In the previous example, this zone is the one sprinkled with water between the two ribs 8 and 9.

This has two advantages: firstly that the painting is simplified and less costly, given that it does not coat the whole reaction chamber 2, but only one part of it; secondly that, since the zones subjected to greater radiation are water cooled, the temperature of the quartz on the water side is relatively cool.

Conversely, where there is no water, notwithstanding the fact that there is less radiation, the temperature is higher on the outer side of the chamber 2 and this causes the gold coating to detach irrespective of whether it is applied by painting or deposited by other methods (PVD for example), since gold (or other metals) has a greater thermal expansion coefficient than quartz (in the order of 5×10⁻⁷ l/K).

In these zones where there is no water, the losses due to radiation can however be reduced by using screens 13 and 14, which thus act as reflectors. In this case, screens 13 and 14 can be made of metal material and/or optionally coated with gold or another highly-reflective material.

Lastly, it should be noted that the selective cooling of the reaction chamber can also be applied to vertical epitaxial reactors, with possible modifications due to the truncated-pyramid shape of the susceptor and of the bell shape of the reaction chamber.

These and other embodiments fall nevertheless within the scope of the following claims.

1-17. (canceled)

18. Method of cooling the reaction chamber (2) of a reactor (1) for chemical vapour deposition, wherein at least one predetermined zone of the wall of the reaction chamber (2) is selectively cooled with a fluid in order to remove a different heat flux compared with the adjacent zones, thereby obtaining a substantially uniform temperature distribution of the reaction chamber (2) , characterised in that the fluid used for selectively cooling said at least one zone is water or another liquid, whereas the adjacent zones are cooled using air or another gas.

19. Method according to claim 18, wherein the at least one selectively-cooled zone is separated from the adjacent zones to avoid the fluid from passing from the former to the latter.

20. Method according to claim 18, wherein the reaction chamber (2) contains a susceptor (5) and said at least one selectively-cooled zone is in a position that is substantially in front of the susceptor (5).

21. Method according to claim 18, wherein said air or other gas is supplied using forced ventilation.

22. Reactor (1) for chemical vapour deposition adapted to carry out the method according to claim 18, comprising a reaction chamber (2), a susceptor (5) placed in said reaction chamber, means (15, 16, 24, 25) for selectively distributing a cooling fluid on at least one predetermined zone of the reaction chamber (2), said cooling fluid being water or another liquid, characterized by being adapted to cool zones of the reaction chamber (2) adjacent to said predetermined zone through air or another gas.

23. Reactor according to claim 22, comprising means for supplying said air or other gas using forced ventilation.

24. Reactor according to claim 22, comprising a screening (13, 14) fitted to the reaction chamber (2) in order to prevent the fluid from licking the zones adjacent to the selectively-cooled zone.

25. Reactor according to claim 24, wherein the reaction chamber (2) comprises a ribbing (8, 9) on its surface suitable for delimiting said selectively-cooled zone from the zones adjacent thereto.

26. Reactor according to claim 24, wherein the susceptor (5) is a disc susceptor and the reaction chamber (2) has a substantially parallelepipedal shape with an inlet opening (3) and an outlet opening (4) on respective opposite faces for the flow of the reaction gases in a substantially-horizontal direction, and wherein the screening (13, 14) extends from said opposite faces, leaving the zone above the susceptor free.

27. Reactor according to claim 24, wherein the cooling liquid is distributed over the screening (13, 14) from which it flows over the zone of the reaction chamber (2) that is located above the susceptor (5).

28. Reactor according to claim 25, wherein said ribbing (8,9) is substantially arcuate for deliminting the zone of the reaction Chamber (2) that is located above the susceptor (5) and is open on the sides to let the cooling liquid flow out laterally.

29. Reactor according to claim 22, comprising nozzles (24, 25) that are suitable for spraying the cooling liquid centrally with respect to the zone of the reaction chamber (2) that is located above the susceptor (5).

30. Reactor according to claim 22, wherein the selectively-cooled zone of the reaction chamber (2) is coated with a reflective layer.

31. Reactor according to claim 22, wherein a screening (13, 14) is fitted to the reaction chamber (2) and is made of metal material or coated with reflective material.

32. Reaction chamber for a reactor according to claim 22, having a substantially parallelepipedal shape and comprising a ribbing (8,9) on its surface suitable for delimiting a selectively-cooled zone from zones adjacent thereto.

33. Reaction chamber according to claim 32, comprising on its upper surface a pair of substantially arcuate ribs (8, 9), that extend preferably from one side of the chamber to the other side, to delimit the selectively-cooled zone.

34. Reaction chamber according to claim 33, wherein the zone delimited by said ribs (8, 9) is coated with a reflective layer.
